(19) United States
(12) Patent Application Publication
(10) Pub. No.: US 2007/0099426 A1
(43) Pub. Date: May 3, 2007

(54) Polishing method, polishing apparatus, and electrolytic polishing apparatus

(76) Inventors: Manabu Tsujimura, Tokyo (JP); Akira Fukunaga, Tokyo (JP); Yutaka Wada, Tokyo (JP); Itsuki Kobata, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/316,845

(22) Filed: Dec. 27, 2005

(30) Foreign Application Priority Data
Oct. 27, 2005 (JP) 2005-313234

(51) Int. Cl. H01L 21/302; H01L 21/461

(52) U.S. Cl. 438/691

(57) ABSTRACT

A polishing method polishes a substrate so as to remove an interconnect metal film and a barrier film formed on portions other than interconnect recesses. The method includes performing a first polishing process of polishing a surface of the substrate After performing the first polishing process, the surface of the substrate is cleaned. After cleaning, a second polishing process is performed for further polishing the surface of the substrate. At least one of performing the first polishing process and performing the second polishing process includes performing electrolytic polishing.

### BACKGROUND OF THE INVENTION

1. Field of the Invention:

The present invention relates to a polishing method and a polishing apparatus, and more particularly to a polishing method and a polishing apparatus for polishing a substrate, such as a semiconductor wafer, having an interconnect material (metal), e.g., copper, embedded in fine interconnect recesses formed on a dielectric (interlevel dielectric) on the substrate to thereby form interconnects in the substrate.

The present invention also relates to an electrolytic polishing apparatus suitable for use in the above polishing apparatus.

2. Description of the Related Art:

A so-called damascene process, which comprises embedding an interconnect metal into interconnect recesses such as trenches and via holes formed on a dielectric, has been used as a process of forming interconnects in a semiconductor device. According to the damascene process, the interconnect recesses are formed on the dielectric (interlevel dielectric), which is composed of SiO₂, SiOF, SiOC, Low-k material, or the like, of the substrate. Subsequently, a barrier film of titanium, tantalum, tungsten, ruthenium, and/or their alloys is formed on an entire surface of the dielectric including the interconnect recesses. Then, an interconnect metal film of aluminum, copper, silver, gold, or their alloys is formed on a surface of the barrier film to fill the interconnect recesses with the interconnect material. Thereafter, extra interconnect metal film and the barrier film formed on portions other than the interconnect recesses are removed. In current high-speed devices, copper or copper alloy is generally used as the interconnect metal, and so-called Low-k material is increasingly used as the dielectric.

In the damascene process, formation of the interconnect recesses is generally performed by dry etching or the like, and formation of the barrier film is generally performed by a dry process such as PVD (physical vapor deposition), CVD (chemical vapor deposition), or ALD (atomic layer deposition). Formation of the interconnect metal film is performed by a wet process such as electroplating or electroless plating, or a dry process such as PVD, CVD, or ALD. Recently, electroplating has been widely used to form an interconnect metal film. In a case where the interconnect metal film is to be formed by electroplating onto a barrier film having low electrical conductivity, a seed film, serving as an electric supply layer, is typically formed in advance on a surface of the barrier film subsequent to formation of the barrier film. Generally, extra interconnect metal and the barrier film are removed by a planarizing method such as chemical mechanical polishing (CMP) or electrolytic polishing (composite electrolytic polishing).

FIGS. 1A through 1C of the accompanying drawings show successive steps of a process of forming copper interconnects in a semiconductor device. As shown in FIG. 1A, an insulating film (interlevel dielectric) 302 composed of, for example, SiO₂ or Low-k material is deposited on a conductive layer 301a formed on a semiconductor base 301 where semiconductor elements have been formed thereon Then, via holes 303 and trenches 304 are formed in the insulating film 302 by performing a lithography/etching technique. A barrier film 305 of Ta, TaN, or the like is formed on the insulating film 302 including the via holes 303 and the trenches 304, and then a seed film 306, serving as an electric supply layer for electroplating, is formed on the barrier film 305 by performing sputtering or other techniques.

Then, as shown in FIG. 1B, copper plating is performed on a surface of the semiconductor substrate W so as to fill the via holes 303 and the trenches 304 with copper, and, at the same time, deposit a copper film 307 as an interconnect metal film onto the insulating film 302. Thereafter, the copper film 307, the seed film 306, and the barrier film 305 on the insulating film 302 are removed by chemical mechanical polishing (CMP) or other techniques, so that a surface of the copper film 307 filling the via holes 303 and the trenches 34 is substantially flush with the surface of the insulating film 302 As a result, as shown in FIG 1C, interconnects 308 comprising the seed film 306 and the copper film 307 are formed in the insulating film 302.

In a process of forming interconnects which are as fine as 65 nm or less, Low-k material is expected to be used as the insulating film (dielectric). The Low-k material has low mechanical strength compared to conventional material such as SiO₂, SiOF, or SiOC Accordingly, polishing of an interconnect metal film on the insulating film of Low-k material at excessive polishing pressure is not preferable in view of preventing damage to the insulating film (i.e., Low-k material). Even if mechanical strength of the Low-k material is improved, high polishing pressure may cause damage to surfaces of the fine interconnects after polishing. Such damage to these polished surfaces would cause adverse influences such as an increase in interconnect resistance. Therefore, there is the need for lowering polishing pressure.

### SUMMARY OF THE INVENTION

The present invention has been made in view of the above drawbacks. It is therefore an object of the present invention to provide a polishing method, a polishing apparatus, and an electrolytic polishing apparatus which can prevent damage to an insulating film and an interconnect metal film during a process of forming interconnects which are as fine as 65 nm or less, and can thus produce a highly durable and high-speed device.

In order to solve the above drawbacks, according to one aspect of the present invention, there is provided a polishing method of polishing a substrate so as to remove an interconnect metal film and a barrier film formed on portions other than interconnect recesses. This method comprises: performing a first polishing process of polishing a surface of the substrate; after performing the first polishing process, cleaning the surface of the substrate; and then, performing a second polishing process of farther polishing the surface of the substrate. At least one of performing the first polishing process and performing the second polishing process comprises performing electrolytic polishing.

Because the surface of the substrate is cleaned between the first polishing process and the second polishing process, successive polishing can be performed using polishing liquids having greatly different compositions. Accordingly, a manner of polishing can be diversified and, as a result, formation of interconnects with less damage can be achieved.

Further, according to the present invention, electrolytic polishing, which generally has a little effect on device elements such as interconnects, is employed as at least part of a polishing process. For example, electrolytic polishing may constitute most part of polishing, i.e., removing most part of the interconnect metal film formed on portions other than the interconnect recesses. Use of electrolytic polishing in this manner can greatly reduce damage to an interconnect structure. Therefore, it is possible to prevent damage to an insulating film and an interconnect metal film during a process of forming interconnects which are as fine as 65 nm or less, and thus to produce a highly durable and high-speed device.

Electrolytic polishing includes general electrolytic polishing using phosphoric acid as an electrolytic solution (polishing liquid) for dissolving an interconnect metal film by anode polarization, and composite electrolytic polishing comprising electrolytic polishing and low-pressure mechanical polishing. General electrolytic polishing performs a polishing process utilizing only electrolytic oxidation and etching, and composite electrolytic polishing performs a polishing process utilizing a combination of electrolytic oxidation, etching, and mechanical polishing.

In a preferred aspect of the present invention, the electrolytic polishing is performed using an electrolytic solution having an electrical conductivity of not less than 50 mS/cm.

By allowing high current to flow through the electrolytic solution, electrolytic polishing can be efficiently performed, even if voltage is low. Use of high voltage results not only in high electric power expense, but also in high production cost of the apparatus because of a need for a high-capacity rectifier. Use of the electrolytic solution polishing liquid) having an electrical conductivity of not less than 50 mS/cm can lower the voltage required for electrolytic polishing to less than 10 V. Therefore, electrolytic polishing can be efficiently performed.

In a preferred aspect of the present invention, at least one of performing the first polishing process and performing the second polishing process comprises performing CMP.

In general, electrolytic polishing (composite electrolytic polishing) can perform polishing with a little damage to interconnects, but may be inferior in eliminating level differences on a surface of an interconnect metal film. Further, in general, an electrical conductivity of the barrier film is greatly lower than that of the interconnect metal film Accordingly, electrical resistance increases at a time the barrier film is exposed, and hence, electrolytic polishing may be stopped with part of the interconnect metal film remaining, even if electrolytic polishing is requited to be continued. According to the present invention, electrolytic polishing (composite electrolytic polishing) can be performed so as to remove most of the interconnect metal film, and subsequently CMP, which is excellent in eliminating level differences, can be performed so as to remove a remaining interconnect metal film, thus enhancing a flatness of a polished surface of the substrate. In this case, by switching from electrolytic polishing to CMP at a time the barrier film is exposed, the remaining interconnect metal film and the barrier film underneath the interconnect metal film can be sufficiently removed.

In a preferred aspect of the present invention, cleaning the surface of the substrate comprises cleaning and rinsing the surface of the substrate using a cleaning unit.

In a preferred aspect of the present invention, cleaning the surface of the substrate comprises performing a water polishing process of polishing the substrate on a polishing table while supplying water to the substrate.

In a preferred aspect of the present invention, cleaning the surface of the substrate comprises rinsing the surface of the substrate at a position laterally of a polishing table.

In a preferred aspect of the present invention, cleaning of the surface of the substrate is performed until an electrical conductivity of a waste cleaning liquid discharged during cleaning the surface of the substrate is reduced to at most one-third of an electrical conductivity of a polishing liquid used in the second polishing process.

In electrolytic polishing, a thick electrolytic solution (polishing liquid) having a high electrical conductivity is preferably used. On the other hand, in CMP, a polishing liquid having a high electrical conductivity may cause aggregation of polishing particles, thus deteriorating a polishing property. Accordingly, a thin polishing liquid having a low electrical conductivity in the range o, for example, 1 to 10 mS/cm is generally used in CMP However, if electrolytic polishing (the first polishing process) is performed using a thick electrolytic solution (polishing liquid) having a high electrical conductivity and CMP (the second polishing process) is subsequently performed without cleaning the substrate to which the electrolytic solution adheres, then the polishing liquid used in CMP becomes thick, and hence, a polishing property is deteriorated. In view of such a drawback, cleaning and rinsing are performed until the electrical conductivity of the waste cleaning liquid is reduced to at most one-third of, preferably one-tenth of, more preferably a level substantially equal to the electrical conductivity of the polishing liquid used in the second polishing process, whereby the second polishing process can be performed without deteriorating the polishing property.

In a preferred aspect of the present invention, the polishing method further comprises monitoring an electrical conductivity of a waste cleaning liquid discharged during cleaning the surface of the substrate using an electrical conductivity meter.

By monitoring the electrical conductivity of the waste cleaning liquid using the electrical conductivity meter, an effect of cleaning can be confirmed and polishing can be sufficiently performed.

In a preferred aspect of the present invention, the polishing method further comprises conditioning a polishing surface before or after performing the electrolytic polishing.

The present invention can prevent polishing liquids from being mixed with each other, and therefore, the same polishing surface can be used in the first polishing process and the second polishing process.

According to another aspect of the present invention, there is provided a polishing apparatus comprising; a first polishing unit including an electrolytic polishing apparatus for polishing a substrate; at least one cleaning unit for cleaning and rinsing the substrate, a second polishing unit for further polishing the substrate after processed by the electrolytic polishing apparatus and the at least one cleaning unit; and at least one drying unit for drying the substrate.

According to the present invention, the first polishing unit, the cleaning unit, the second polishing unit, and the drying unit can perform a series of processes in a single polishing apparatus. Further, the substrate, which is introduced to the polishing apparatus in a dry state, can be processed and removed in a dry state from the polishing apparatus. Therefore, a state of the substrate after polishing can be consistent with a state of the substrate before polishing.

In a preferred aspect of the present invention, the second polishing unit includes a CMP apparatus.

In a preferred aspect of the present invention, the electrolytic polishing apparatus comprises a conditioning member for conditioning a polishing surface, and also serves as the CMP apparatus.

Conditioning of the polishing surface can prevent polishing liquids from being mixed with each other, and therefore, the first polishing process and the second polishing process can be performed in the same electrolytic polishing apparatus. Examples of the conditioning member include an atomizer which supplies pressurized pure water or a chemical liquid, which accelerates removal of the electrolytic solution, onto a polishing surface.

In a preferred aspect of the present invention, the polishing apparatus further comprises an electrical conductivity meter provided in a drain passage of the cleaning unit for measuring electrical conductivity of a waste rinsing liquid flowing through the drain passage.

According to another aspect of the present invention, there is provided an electrolytic polishing apparatus comprising: a first electrode connected to one of poles of a power source; a polishing table electrically connected to the first electrode; a polishing pad provided on an upper surface of the polishing table and having a polishing surface; a top ring operable to hold a substrate and press the substrate against the polishing surface at a pressure of not more than 7 kPa; a second electrode connected to another of the poles of the power source for supplying electricity to the substrate; a liquid supply unit for supplying a liquid onto the polishing surface; a conditioning member for conditioning the polishing surface; and a relative movement mechanism for providing relative movement between the substrate held by the top ring and the polishing pad.

With this structure, by conditioning the polishing surface of the polishing pad with use of the conditioning member, polishing by-products and the like can be removed from the polishing pad, and hence a polishing property of the polishing pad can be maintained. After conditioning using water, e.g., normal dressing or atomizing, is performed, it is preferable that the polishing table with the polishing pad is rotated at a speed of 50 to 100 min⁻¹ for several seconds so as to drain the polishing pad. This operation can prevent a change in concentration of the electrolytic solution.

In a preferred aspect of the present invention, the conditioning member comprises one of a dresser having diamond particles electrodeposited thereon and a brush.

In a preferred aspect of the present invention, the electrolytic polishing apparatus further comprises a counter electrode disposed so as to face the first electrode for conditioning the first electrode by applying a voltage such that the first electrode has polarity reversed from when electrolytic polishing is performed.

Conditioning of the first electrode can remove polishing by-products deposited on the first electrode due to electrolytic polishing. Therefore, electrode potential and electrode resistance, which affect a polishing property, can be prevented from changing.

In a preferred aspect of the present invention, the electrolytic polishing apparatus further comprises an atomizer for supplying pure water or a chemical liquid onto the polishing surface.

With this structure, the pure water or chemical liquid supplied from the atomizer onto the polishing pad can remove unwanted substances, e.g., polishing by-products adhering to the polishing surface, and the remaining electrolytic solution At the same time, unwanted substances, such as reaction by-products deposited on the surface of the first electrode exposed in openings formed in the polishing pad, can be removed.

In a preferred aspect of the present invention, the polishing pad has through-holes extending therethrough in a direction perpendicular to the polishing surface, or the polishing pad is made of material having liquid permeability.

With this structure, electricity can be supplied to the substrate contacting the polishing pad through the electrolytic solution in the through-holes, whereby electrolytic polishing can be performed. The polishing pad having the through-holes over the entire surface thereof may have grid-like or annular grooves on the surface thereof. If the polishing pad itself has liquid permeability, it is not necessary to provide the through-holes in the polishing pad.

In a preferred aspect of the present invention, the electrolytic polishing apparatus further comprises an electrode conditioner for conditioning the second electrode.

With this structure, the electrode conditioner can remove polishing by-products, oxide, and the like deposited on a surface of the second electrode during polishing.

In a preferred aspect of the present invention, the electrolytic polishing apparatus further comprises an electrode conditioner cleaning unit for cleaning the electrode conditioner.

In a preferred aspect of the present invention, the electrolytic polishing apparatus further comprises a counter electrode conditioner for conditioning the counter electrode.

According to another aspect of the present invention, there is provided an electrolytic polishing apparatus comprising: a first electrode connected to one of poles of a power source; a polishing table electrically connected to the first electrode; a polishing pad provided on an upper surface of the polishing table and having a polishing surface; a top ring operable to hold a substrate and press the substrate against the polishing surface; a second electrode connected to another of the poles of the power source for supplying electricity to the substrate; a liquid supply unit for supplying a liquid onto the polishing surface; a conditioning member for conditioning the polishing surface; and a relative movement mechanism for providing relative movement between the substrate held by the top ring and the polishing pad. The liquid supply unit is connected to a polishing liquid supply line and an electrolytic solution supply line.

With this structure, electrolytic polishing can be performed while supplying electrolytic solution onto the polishing pad through the electrolytic solution supply line, and CMP can be performed while supplying the polishing liquid onto the polishing pad through the polishing liquid supply line. Further, conditioning of the polishing pad can be performed between electrolytic polishing and CMP, thus preventing mixing of the electrolytic solution and the polishing liquid.

According to another aspect of the present invention, there is provided an electrolytic polishing apparatus comprising: a first electrode connected to one of poles of a power source; a polishing table electrically connected to the first electrode; a polishing pad provided on an upper surface of the polishing table and having a polishing surface; a top ring operable to hold a substrate and press the substrate against the polishing surface; a second electrode connected to another of the poles of the power source for supplying electricity to the substrate; a liquid supply unit for supplying a liquid onto the polishing surface; a conditioning member for conditioning the polishing surface; and a relative movement mechanism for providing relative movement between the substrate held by the top ring and the polishing pad. The liquid supply unit is connected to a polishing liquid supply line and a supporting electrolyte supply line.

In general, there are several types of electrolytic solutions and polishing liquids. For example, there is an electrolytic solution comprising a supporting electrolyte and a polishing liquid to be used in CMP. Further, in a case of polishing interconnect metal such as copper by electrolytic polishing and then performing CMP to remove copper remaining on a barrier film, a polishing liquid for use in CMP may comprise a base liquid of the electrolytic solution to be used in electrolytic polishing. According to this electrolytic polishing apparatus, in such cases, CMP can be performed while supplying the polishing liquid onto the polishing surface through the polishing liquid supply line, and electrolytic polishing can be performed while supplying the polishing liquid and the supporting electrolyte onto the polishing surface through the polishing liquid supply line and the supporting electrolyte supply line, respectively.

In a preferred aspect of the present invention, the liquid supply unit is further connected to an additive supply line.

With this structure, CMP can be performed using a polishing liquid containing an additive by supplying the polishing liquid onto the polishing surface through the polishing liquid supply line while supplying an additive such as an oxidizing agent onto the polishing surface through the additive supply line. In this case, the additive can be supplied to the polishing surface as needed.

In a preferred aspect of the present invention, the polishing liquid supply line and the supporting electrolyte supply line are connected to the liquid supply unit via a buffer for mixing liquids.

With this structure, the polishing liquid supplied through the polishing liquid supply line and the supporting electrolyte supplied through the supporting electrolyte supply line can be mixed with each other in the buffer to thereby produce in advance an electrolytic solution stored in the buffer, so that this electrolytic solution can be supplied from the buffer onto the polishing pad.

In a preferred aspect of the present invention, the liquid supply unit is further connected to a pure water supply line.

With this structure, after polishing, water polishing can be performed to clean the substrate while supplying pure water onto the polishing surface of the polishing pad.

### BRIEF DESCRIPTION OF THE DRAWINGS

FIGS. 1A through 1C show successive steps of a process of forming copper interconnects in a semiconductor device;

FIG. 2 is a plan view showing a layout of various components of a polishing apparatus according to an embodiment of the present invention;

FIG. 3 is a plan view showing an essential part of an electrolytic polishing apparatus according to an embodiment of the present invention, which is incorporated in the polishing apparatus shown in FIG. 2;

FIG. 4 is a cross-sectional view showing an essential part of an electrolytic polishing apparatus according to the embodiment of the present invention, which is incorporated in the polishing apparatus shown in FIG. 2;

FIG. 5 is a cross-sectional view showing an example of a cleaning unit incorporated in the polishing apparatus shown in FIG. 2;

FIG. 6 is a graph showing a relationship between flow rate of an electrolytic solution, electrolytic current, and polishing torque during electrolytic polishing;

FIG. 7 shows another example of the cleaning unit;

FIG. 8 shows another example of the cleaning unit;

FIG. 9 is a plan view showing an essential part of an electrolytic polishing apparatus according to another embodiment of the present invention;

FIG. 10 is a cross-sectional view showing an essential part of an electrolytic polishing apparatus according to another embodiment of the present invention;

FIG. 11 is a plan view showing an essential part of an electrolytic polishing apparatus according to another embodiment of the present invention;

FIG. 12 is a cross-sectional view showing an essential part of an electrolytic polishing apparatus according to another embodiment of the present invention;

FIG. 13 is a plan view showing an essential part of an electrolytic polishing apparatus according to another embodiment of the present invention;

FIG. 14 is a plan view showing an essential part of an electrolytic polishing apparatus according to another embodiment of the present invention;

FIG. 15 is a plan view showing an essential part of an electrolytic polishing apparatus according to another embodiment of the present invention;

FIG. 16 is a plan view showing an essential part of an electrolytic polishing apparatus according to another embodiment of the present invention;

FIG. 17 is a plan view showing an essential part of an electrolytic polishing apparatus according to another embodiment of the present invention;

FIG. 18 is a plan view showing an essential part of an electrolytic polishing apparatus according to another embodiment of the present invention;

FIG. 19 is a plan view showing an essential part of an electrolytic polishing apparatus according to another embodiment of the present invention;

FIG. 20 is a cross-sectional view showing a slit nozzle shown in FIG. 19; and

FIG. 21 is a perspective view showing the slit nozzle shown in FIG. 19.

### DETAILED DESCRIPTION OF THE PREFERRED EMBODIMENTS

Embodiments of the present invention will be described below with reference to the drawings.

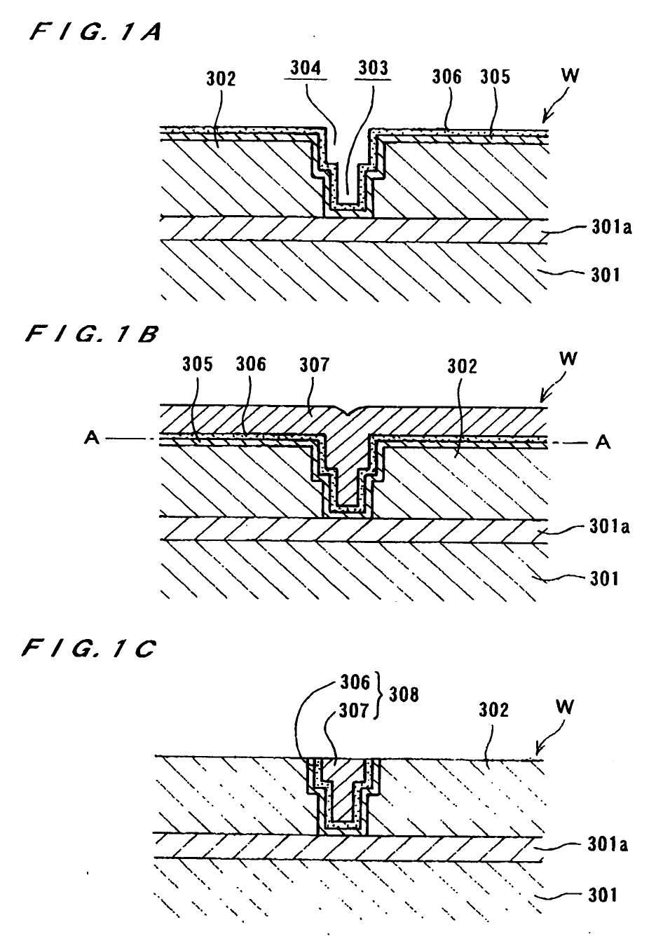

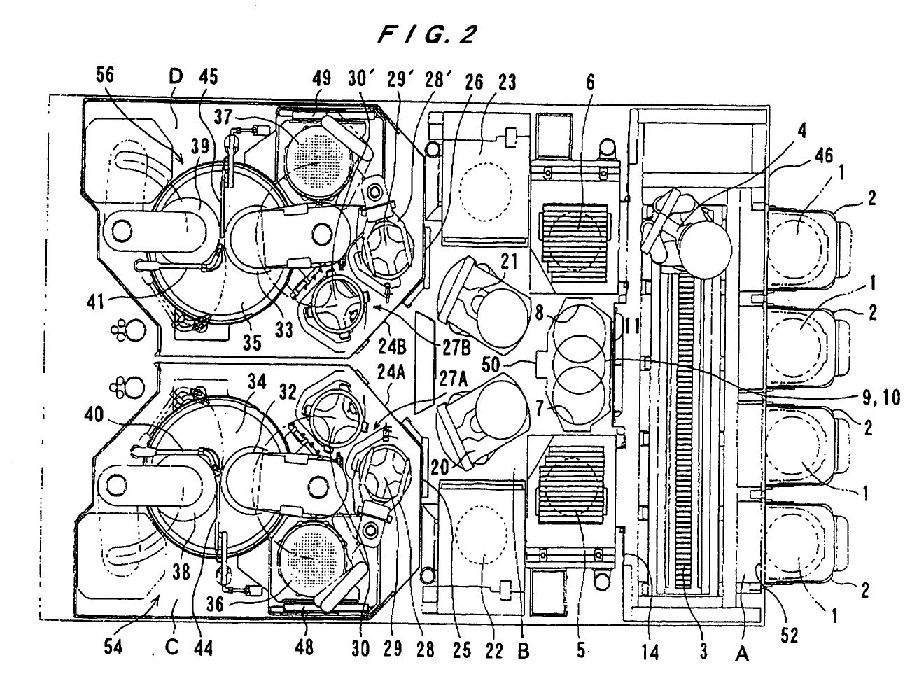

FIG. 2 is a plan view showing a layout of various components of a polishing apparatus according to an embodiment of the present invention. This polishing apparatus is used for forming interconnects. For example, as shown in FIG. 1B, copper plating is performed on a substrate W so as to fill via hales 303 and trenches 304 with copper and to deposit a copper film 307 as an interconnect metal film onto an insulating film (dielectric) 302. Then, the substrate W is introduced into the polishing apparatus, where polishing is performed on a surface of the substrate W to thereby remove the copper film 307, a seed film 306, and a barrier film 305 on the insulating film 302. As a result, as shown in FIG. 1C, interconnects 308 comprising the seed film 306 and the copper film 307 are formed in the insulating film 302.

The polishing apparatus according to the present embodiment comprises four load-unload stages 2 on which substrate cassettes 1 are placed, respectively. Each of the substrate cassettes 1 stores plural substrates W each having the copper film 307 (see FIG. 1B) as an interconnect metal film. A transfer robot 4 having two hands is provided on a traveling mechanism 3 so that the hands of the transfer robot 4 can reach respective substrate cassettes 1 on respective load-unload stages 2. The traveling mechanism 3 comprises a linear motor, and can thus allow the transfer robot 4 to quickly and stably transfer a substrate with increased weight due to a large diameter.

In this embodiment, SMIF (Standard Manufacturing Interface) pod or FOUP (Front Opening Unified Pod) is used as the load-unload stages 2 on which the substrate cassettes 1 are placed. The load-unload stages 2 are disposed outside a housing 46 of the polishing apparatus. SMIF and FOUP are hermetic vessels in which substrates are accommodated, and each of them comprises a partition wall allowing an inner space therein to maintain its conditions independently from an outer space. SMIF or FOUP, which is used as the load-unload stages 2, has shutters operable to be opened together with shutters 52 of the housing 46, so that the polishing apparatus and the substrate cassettes 1 are coupled integrally to each other. After polishing, the shutters of SMIF or FOUP are closed, so that the substrate cassettes 1 are separated from the polishing apparatus. The substrate cassettes 1 are automatically or manually transferred to other processes, and therefore, internal atmospheres of the substrate cassettes 1 are required to be kept clean.

For this reason, a chemical filter is provided so as to form downflow of a clean air at an upper region of an area A through which a substrate passes right before being returned to the substrate cassette 1. In this embodiment, the linear motor is used to move the transfer robot 4. Therefore, dust can be prevented from rising, and an atmosphere of area A can thus be kept clean.

In order to keep the substrates in the substrate cassettes 1 clean, each of the substrate cassettes 1 may comprise a hermetic vessel such as SMIF or FOUP in which a chemical filter and a fan are disposed so as to constitute a clean box which can keep itself clean

Two drying units 5 and 6 are disposed at an opposite side of the substrate cassettes 1 with respect to the traveling mechanism 3. The drying units 5 and 6 are disposed at positions where the hands of the transfer robot 4 can reach the drying units 5 and 6. A substrate station 50 having four substrate supports 7, 8, 9 and 10 is provided between the two drying units 5 and 6 at a position where the hands of the transfer robot 4 can reach the substrate station 50.

The drying units 5 and 6 and the substrate supports 7, 8, 9 and 10 are disposed in an area B, and the substrate cassettes 1 and the transfer robot 4 are disposed in area A Area A and area B are partitioned by a partition wall 14 so that cleanliness in area A and area B can be separated. The partition wall 14 has an opening for allowing the substrates to be transferred between area A and area B, and a shutter 11 is provided so as to close the opening. A transfer robot 20 is disposed at a position where hands thereof can reach the drying unit 5 and the three substrate supports 7, 9 and 10, and a transfer robot 21 is disposed at a position where hands thereof can reach the drying unit 6 and the three substrate supports 8, 9 and 10.

A cleaning unit 22 is disposed adjacent to the drying unit 5 at a position where the hands of the transfer robot 20 can reach the cleaning unit 22. A cleaning unit 23 is disposed adjacent to the drying unit 6 at a position where the hands of the transfer robot 21 can reach the cleaning unit 23.

The drying units S and 6, the cleaning units 22 and 23, the substrate supports 7, 8, 9 and 10 of the substrate station 50, and the transfer robots 20 and 21 are all disposed in area B. Pressure in area B is adjusted so as to be lower than pressure in area A.

The polishing apparatus comprises the housing 46 surrounding these respective units, and an internal space of the housing 46 is divided by partition walls 24A and 24B into plural chambers including area A and area B.

Two areas C and D are defined by the partition walls 24A and 24B, respectively, and two polishing chambers, which are separated from area B, are formed in areas C and D, respectively. A first polishing unit comprising an electrolytic polishing apparatus 54 is disposed in area C, and a second polishing unit comprising a CMP apparatus 56 is disposed in area D.

Specifically, the electrolytic polishing apparatus (i.e., the first polishing unit) 54 in area C comprises polishing tables 34 and 36, a top ring 32, an electrolytic solution supply nozzle 40 serving as a liquid supply unit for supplying an electrolytic solution (polishing liquid) onto the polishing table 34, a dresser 38 for dressing the polishing table 34, and a dresser 48 for dressing the polishing table 36. The CMP apparatus (i.e., the second polishing unit) 56 in area D comprises polishing tables 35 and 37, a top ring 33, a polishing liquid supply nozzle 41 for supplying a polishing liquid onto the polishing table 35, a dresser 39 for dressing the polishing table 35, and a dresser 49 for dressing the polishing table 37.

Although each of the electrolytic polishing apparatus 54 and the CMP apparatus 56 of this embodiment has two polishing tables so as to enable the apparatuses 54 and 56 to perform multistage polishing, the polishing tables 36 and 37 may be omitted.

The electrolytic polishing apparatus (i.e., the first polishing unit) 54 further comprises, in addition to mechanical dresser 38, an atomizer 44 as a dresser utilizing fluid pressure. The CMP apparatus (i.e., the second polishing unit) 56 also comprises, in addition to mechanical dresser 39, an atomizer 45 as a dresser utilizing fluid pressure. Generally, an atomizer atomizes a mixed fluid of a liquid (e.g., pure water) and a gas (e.g., nitrogen) and ejects this atomized fluid to a polishing surface through a plurality of nozzles. A main object of the atomizer is to wash away polishing dregs and abrasive particles which are firmly deposited on the polishing surface. Cleaning (i.e., atomizing) of the polishing surface by the atomizers 44 and 45 utilizing fluid pressure, and conditioning (dressing) of the polishing surface by the dressers 38 and 39 utilizing mechanical contact, can achieve desirable conditioning, i.e., regeneration of a polishing surface.

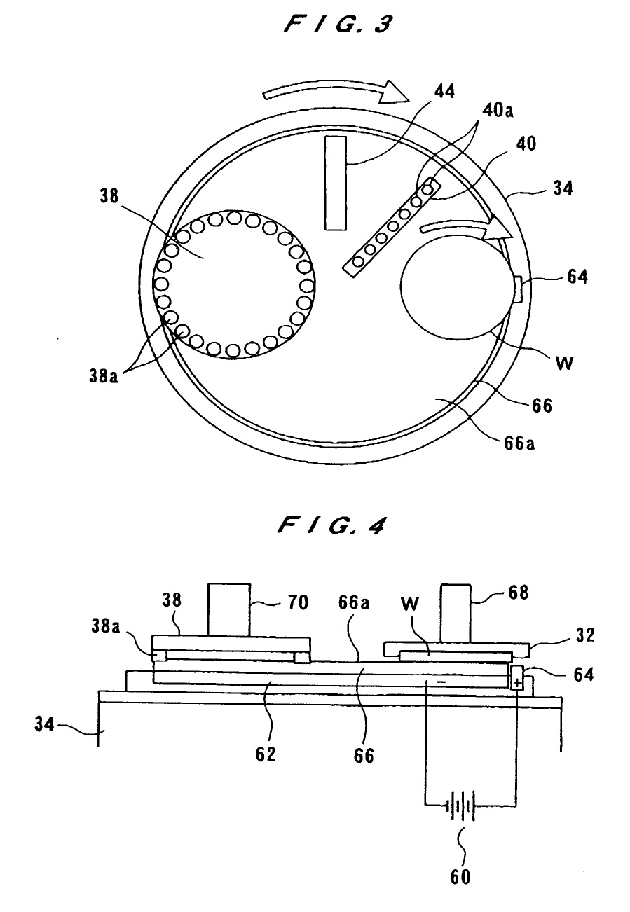

FIGS. 3 and 4 show an essential part of the electrolytic polishing apparatus (first polishing unit) 54. The CMP apparatus (second polishing unit) 56 has substantially the same structures as the electrolytic polishing apparatus 54 except no electrodes (i.e., the CMP apparatus 56 does not have a first electrode 62 and a second electrode 64 shown in FIGS. 3 and 4), and will not be described in detail.

The polishing table 34 of the electrolytic polishing apparatus 54 is made of material having low ionization tendency such as platinum, especially material having ionization tendency lower than that of an object to be polished, e.g., copper. A disk-shaped first electrode (cathode) 62 and a rod-like second electrode (anode) 64 are disposed on an upper surface of the polishing table 34. The first electrode 62 is connected to one of poles of a power source 60, and the second electrode 64 is connected to another of the poles of the power source 60. The first electrode 62 and the second electrode 64 are electrically insulated from each other. An entire upper surface of the first electrode 62 is covered with a polishing pad 66 having an upper surface that serves as a polishing surface 66a.

The top ring 32 is operable to hold the substrate W and lower it to bring a surface (lower surface) of the substrate W into contact with the polishing surface 66a of the polishing pad 66. When the substrate W is brought into contact with the polishing surface 66a, an upper end surface of the second electrode 64 comes into contact with the surface of the substrate W to thereby supply electricity to a conductive material such as a copper film 307 (see FIG. 1B) formed on the surface of the substrate W. The top ring 32 is further operable to press the substrate W against the polishing surface 66a at, for example, not more than 7 kPa which is much lower than pressure (e.g., between 20 and 50 kPa) applied in a CD process.

In order to enhance performance of a device (i.e., to improve RC delay), Low-k material is increasingly used as an insulating film (dielectric). However, use of the Low-k material results in a decrease in mechanical strength of the insulating film itself Consequently, in a polishing process, for example, the Low-k material may be peeled off. Thus, in order to solve such a problem, polishing pressure is required to be lowered. At present, polishing pressure in CMP is about 2 psi (about 14 kPa). In order to cope with a downward trend of mechanical strength of the Low-k material, polishing pressure in a polishing process is required to be further lowered to, for example, at most 1 psi (about 7 kPa).

The polishing pad 66 is formed from IC1000 manufactured by Rodel Nitta Company. IC1000 is a material having a number of through-holes over its entire surface. With this structure, electrical communication is established between the surface of the substrate W contacting the second electrode 64 and the first electrode 62 through an electrolytic solution in the through-holes, whereby electrolytic polishing can be performed. The polishing pad 66 having the through-holes over the entire surface thereof may have grid-like or annular grooves on the surface thereof If the polishing pad 66 itself has liquid permeability, it is not necessary to provide the through-holes in the polishing pad 66.

The top ring 32 is coupled to a lower end of a top ring drive shaft 68, which is rotatable and movable between a predetermined polishing position above the polishing table 34 and a position above a pusher 30 (see FIG. 2). The dresser 38 serves as a conditioning member, and comprises a plurality of ring-shaped brushes 38a attached to a peripheral lower surface thereof The dresser 38 is coupled to a lower end of a dresser drive shaft 70, which is rotatable and movable between a predetermined dressing position above the polishing table 34 and a waiting position located laterally of the dressing position.

The electrolytic solution supply nozzle 40, serving as a liquid supply unit, has plural electrolytic solution supply mouths 40a arranged along a longitudinal direction thereof The electrolytic solution supply nozzle 40 is disposed above the polishing table 34 so as to extend in a radial direction of the polishing table 34. Similarly, the atomizer 44 has plural supply mouths arranged along a longitudinal direction thereof, and is disposed above the polishing table 34 so as to extend in the radial direction of the polishing table 34.

Although not shown in the drawings, a pure water supply nozzle for supplying pure water onto the polishing pad 66, and a dressing liquid supply nozzle for supplying a dressing liquid onto the polishing pad 66, may be provided above the polishing table 34 as needed.

The electrolytic polishing apparatus 54 operates as follows. The top ring 32 holds the substrate W and is moved to the predetermined polishing position above the polishing table 34. Thereafter, the top ring 32 is rotated and lowered to press the surface (lower surface) of the substrate W against the polishing surface 66a of the rotating polishing pad 66 at predetermined pressure. This pressure is, for example, at most 7 kPa, which is much lower than pressure (e.g., between 20 and 50 kPa) in the CMP process. During pressing, the electrolytic solution is supplied onto the polishing surface 66a through the electrolytic solution supply nozzle 40, and a predetermined voltage is applied between the first electrode 62 and the second electrode 64 by the power source 60, whereby a conductive film such as a copper film 307 (see FIG. 1B) on the surface of the substrate W is polished.

When high current flows through the electrolytic solution, electrolytic polishing can be efficiently performed, even if the voltage is low. Accordingly, electrolytic polishing is preferably performed using an electrolytic solution having an electrical conductivity of at least 50 mS/cm. Use of high voltage results not only in high electric power expense, but also in high production cost of the apparatus because of the need for a high-capacity rectifier. Use of the electrolytic solution (polishing liquid) having an electrical conductivity of not less than 50 mS/cm can lower the voltage required for electrolytic polishing to less than 10 V Therefore, electrolytic polishing can be efficiently performed.

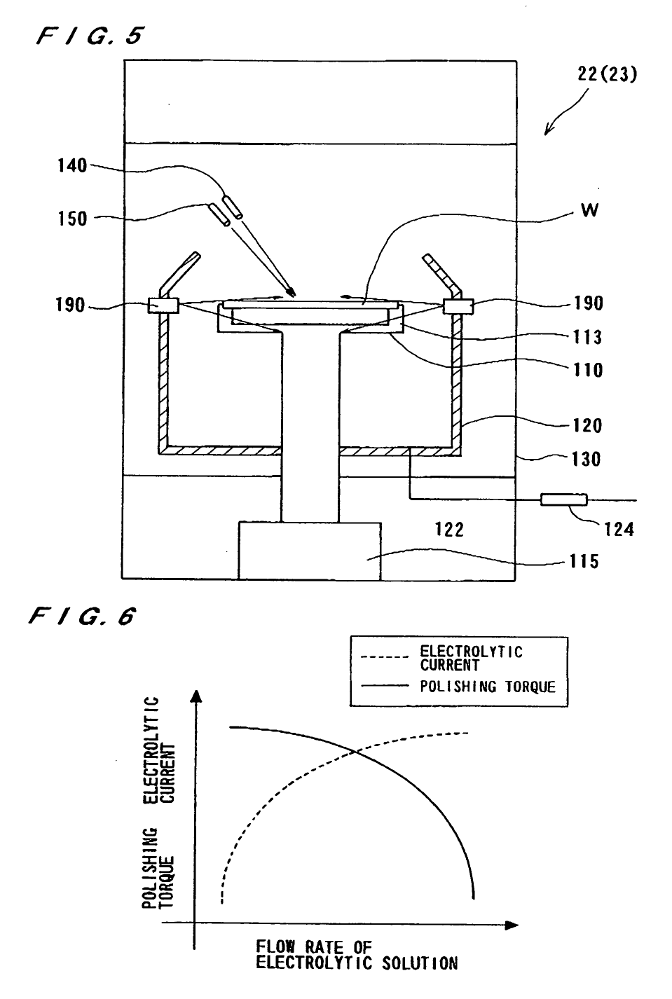

As shown in FIG. 6, during electrolytic polishing, supply of the electrolytic solution onto the polishing pad 66 at high flow rate may cause lowered and non-uniform surface pressure due to hydroplaning. On the other hand, supply of the electrolytic solution at low flow rate may cause lowered electrolyic current because of insufficient supply of the electrolytic solution. Thus, during electrolytic polishing, it is preferable to monitor current value and polishing torque (e.g., top ring torque current value) for determining a suitable flow rate of the electrolytic solution so that a maximal current value can be obtained while maintaining the polishing torque

After electrolytic polishing, supply of the electrolytic solution onto the polishing pad 66 is stopped, and the first electrode 62 and the second electrode 64 are disconnected from the power source 60. Then, the substrate W is pressed against the polishing surface 66a at low pressure while the substrate W is rotated, and simultaneously pure water is supplied onto the polishing pad 66 to thereby clean the surface of the substrate W, i.e., perform so-called water polishing. Then, the top ring 32 is elevated, and the cleaned substrate W is transferred to a subsequent process.

After cleaning the substrate W. the dresser 38 and the atomizer 44 perform conditioning (dressing) on the polishing surface 66a of the polishing pad 66. Specifically, while a lower surface (dressing surface) of the dresser 38 presses the polishing pad 66 at certain pressure, the dresser 38 and the polishing pad 66 are moved relative to each other, and simultaneously a dressing liquid is supplied onto the polishing surface 66a of the polishing pad 66. Additionally, pressurized pure water or a chemical liquid, which accelerates removal of the electrolytic solution, is supplied onto the polishing surface 66a through the atomizer 44 so as to remove (atomize) unwanted substances, e.g., polishing by-products adhering to the polishing surface 66a, and remaining electrolytic solution. At the same time, unwanted substances, such as reaction by-products deposited on a surface of the first electrode 62 exposed in openings or grooves formed in the polishing pad 66, are removed. Atomizing by the atomizer 44 is preferably performed simultaneously with or shortly after dressing by the dresser 38. It is preferable to rotate the polishing table 34 after conditioning for several seconds at a speed in the range of 50 to 100 min⁻¹, which is higher than during conditioning, so as to drain the substrate W. By draining the substrate W after conditioning, a change in concentration of the electrolytic solution can be suppressed.

Conditioning of the polishing surface 66a of the polishing pad 66 by the dresser 38 and the atomizer 44 may be performed before polishing of the substrate in a state such that the top ring 32 is elevated.

As shown in FIG. 2, a reversing device 28 for reversing a substrate is provided in area C separated from area B by the partition wall 24A. The reversing device 28 is disposed at a position where the hands of the transfer robot 20 can reach the reversing device 28. A reversing device 28′ for reversing a substrate is provided in area D separated from area B by the partition wall 24B. The reversing device 28′ is disposed at a position where the hands of the transfer robot 21 can reach the reversing device 28′. The partition walls 24A and 24B, which separate areas C and D from area B, have openings, respectively, for allowing the reversing devices 28 and 28′ to transfer the substrate therethrough. Shutters 25 and 26 are provided at the openings of the partition walls 24A and 24B, respectively.

Each of the reversing devices 28 and 28′ has a chuck mechanism for chucking the substrate, a reversing mechanism for reversing the substrate upside down, and a substrate detecting sensor for detecting whether the chuck mechanism chucks the substrate. The transfer robot 20 transfers the substrate to the reversing device 28, and the transfer robot 21 transfers the substrate to the reversing device 28′.

In area C serving as one of the polishing chambers, a linear transporter (transfer mechanism) 27A is provided for transferring the substrate between the reversing device 28 and the top ring 32 of the electrolytic polishing apparatus 54. In area D serving as the other of the polishing chambers, a linear transporter (transfer mechanism) 27B is provided for transferring the substrate between the reversing device 28′ and the top ring 33 of the CMP apparatus 56. The linear transporter 27A has two stages which linearly reciprocate between a lifter 29 and the pusher 30. The linear transporter 27B also has two stages which linearly reciprocate between a lifter 29′ and a pusher 30′.

FIG. 5 shows an example of the cleaning units 22 and 23. Each of the cleaning units 22 and 23 comprises a substrate holder 110 for detachably holding the substrate W, to be cleaned, with a chuck mechanism 113 which holds a peripheral portion of the substrate W, a cleaning cup 120 surrounding the substrate holder 110 so as to prevent scattering of liquids such as a rinsing liquid, and a cleaning vessel 130 enclosing the cleaning cup 120. Further, each of the cleaning units 22 and 23 comprises a chemical liquid supply nozzle 140 disposed inside the cleaning vessel 130 at a predetermined position for supplying a chemical liquid onto a surface of the substrate W, a rinsing liquid supply nozzle 150 disposed inside the cleaning vessel 130 at a predetermined position for supplying a rinsing liquid such as pure water onto the surface of the substrate W, and cleaning liquid supply nozzles 190 for supplying a cleaning liquid to the substrate holder 110.

The substrate holder 110 is coupled to a drive unit 115, and is rotated by the drive unit 115. A bottom portion of the cleaning cup 120 is connected to a drain passage 122, and an electrical conductivity meter 124 is provided in the drain passage 122 for measuring electrical conductivity of a waste rinsing liquid flowing through the drain passage 122.

Operation of the cleaning units 22 and 23 is performed as follows. The chuck mechanism 113 holds the substrate W, and the drive unit 115 rotates the substrate holder 110. In this state, the chemical liquid (DHF solution) is ejected toward the substrate W through the chemical liquid supply nozzle 140 to thereby clean the surface of the substrate W. Subsequently, supply of the chemical liquid through the chemical liquid supply nozzle 140 is stopped, and then the rinsing liquid (pure water) is ejected toward the substrate W through the rinsing liquid supply nozzle 150 to thereby rinse the surface of the substrate W. At this time, the electrical conductivity meter 124 measures the electrical conductivity of the waste rinsing liquid flowing through the drain passage 122.

When the electrical conductivity of the waste rinsing liquid reaches a predetermined value, or a predetermined period of time has elapsed, supply of the rinsing liquid to the substrate W is stopped, and then the substrate W is rotated by the drive unit 115 at a high speed, so that the substrate W is spin-dried. In this manner, cleaning and rinsing are performed.

This cleaning and rinsing process is preferably performed until the electrical conductivity of the waste rinsing liquid discharged from the cleaning and rinsing process is reduced to at most one-third of, preferably one-tenth of, an electrical conductivity of a polishing liquid used in the CMP process.

In electrolytic polishing, a thick electrolytic solution (polishing liquid) having a high electrical conductivity is preferably used. On the other hand, in CMP, a polishing liquid having a high electrical conductivity may cause aggregation of polishing particles, thus deteriorating a polishing property. Accordingly, a thin polishing liquid having a low electrical conductivity in the range of, for example, 1 to 10 mS/cm is generally used in CMP. However, if electrolytic polishing is performed using a thick electrolytic solution (polishing liquid) having a high electrical conductivity and CMP is subsequently performed without cleaning and rinsing the substrate to which the electrolytic solution adheres, then the polishing liquid used in CMP becomes thick, and hence, a polishing property is deteriorated. In view of such a drawback, cleaning and rinsing are performed until the electrical conductivity of the waste rinsing liquid is reduced to at most one-third of; preferably one-tenth of, more preferably a level substantially equal to the electrical conductivity of the polishing liquid used in CMP, whereby CMP (second polishing) can be performed without deteriorating the polishing property.

Next, operation of the polishing apparatus will be described.

Firstly, the substrate cassette(s) 1, which accommodates plural substrates each having the copper film 307 on the surface thereof (see FIG. 1B), is set on the load-unload stage(s) 2. Then, one of the substrates is removed from the substrate cassette 1 by the transfer robot 4, and is placed onto the substrate station 50. The transfer robot 20 receives the substrate from the substrate station 50, and transfers the substrate to the reversing device 28 in area C, where the substrate is reversed. The lifter 29 receives this reversed substrate from the reversing device 28, and transfers it to the linear transporter 27A. The linear transporter 27A is horizontally moved to place the substrate onto the pusher 30. In this state, the top ring 32 of the electrolytic polishing apparatus (first polishing unit) 54 is moved to a position above the pusher 30.

The top ring 32 receives the substrate from the pusher 30, and holds the substrate inside a guide ring (not shown) by vacuum attraction. While holding the substrate, the top ring 32 is moved from the position above the pusher 30 to the polishing position above the polishing table 34. Then, the top ring 32 is lowered to press the substrate against the polishing surface 66a of the polishing pad 66 at a predetermined pressure of not more than 7 kPa. At the same time, an electrolytic solution, which has an electrical conductivity of not less than 50 mS/cm, is supplied onto the polishing pad 66. As described above, current value and polishing torque (e.g., top ring torque current value) are monitored during electrolytic polishing so that a flow rate of the electrolytic solution suitable for obtaining a maximal current while maintaining the polishing torque is determined. In this manner, the conductive film such as the copper film 307 (see FIG. 1B) on the surface of the substrate W is polished. During polishing of the substrate on the polishing pad 66, the top ring 32 may release the vacuum attraction.

The electrolytic polishing apparatus 54 polishes the copper film 307 (and the seed film 306) until the barrier film 305 is exposed on the surface of the substrate, as indicated by line A-A in FIG. 1B. In this manner, electrolytic polishing, which generally has a little effect on device elements such as interconnects, is employed as at least part of the polishing process. For example, electrolytic polishing may constitute most part of polishing, i.e., removing most part of an interconnect metal film formed on portions other than interconnect recesses. Use of electrolytic polishing in this manner can greatly reduce damage to an interconnect structure.

After the electrolytic polishing apparatus 54 finishes electrolytic polishing, the dresser 38 and the atomizer 44 perform conditioning of the polishing surface 66a of the polishing pad 66, so that the polishing surface 66a can be ready for subsequent polishing.

The substrate, which has been polished by the electrolytic polishing apparatus 54, is transferred again to the position above the pusher 30. The top ring 32 releases the substrate onto the pusher 30, and a cleaning nozzle provided on the pusher 30 cleans a polished surface and a rear surface of the substrate. Then, the linear transporter 27A and the lifter 29 transfer the substrate to the reversing device 28, where the substrate is reversed. The transfer robot 20 transfers this reversed substrate to the cleaning unit 22. In this cleaning unit 22, as described above, the electrical conductivity of the waste rinsing liquid discharged from the cleaning and rinsing process is measured by the electrical conductivity meter 124 so that cleaning and rinsing of the surface of the substrate is performed until the electrical conductivity of the waste rinsing liquid is reduced to at most one-third of, preferably one-tenth of more preferably a level substantially equal to the electrical conductivity of the polishing liquid used in the CMP process. After cleaning and rinsing, the transfer robot 20 transfers the substrate to the substrate station 50, and places it onto the substrate station 50.

Because the substrate is cleaned and rinsed between the first polishing process and the second polishing process, polishing liquids having greatly different compositions can be used in these respective polishing processes. Accordingly, a manner of polishing can be diversified and, as a result, formation of interconnects with less damage can be achieved.

The transfer robot 21 holds the substrate on the substrate station 50, and transfers it to the reversing device 28′ in area D, where the substrate is reversed. The lifter 29′ receives this reversed substrate from the reversing device 28′, and transfers it to the linear transporter 27B. The linear transporter 27B is horizontally moved to place the substrate onto the pusher 30′. In this state, the top ring 33 of the CMP apparatus (second polishing unit) 56 is moved to a position above the pusher 30′.

The top ring 33 receives the substrate from the pusher 30′, and holds the substrate inside a guide ring (not shown) by vacuum attraction. While holding the substrate, the top ring 33 is moved from the position above the pusher 30′ to the polishing position above the polishing table 35. Then, the top ring 33 is lowered to press the substrate against a polishing surface of a polishing pad attached to an upper surface of the polishing table 35 at predetermined pressure. At the same time, a polishing liquid is supplied onto the polishing pad through the polishing liquid supply nozzle 41. In this state, the top ring 33 and the polishing table 35 are rotated to thereby further polish the surface of the substrate. During polishing of the substrate on the polishing pad, the top ring 33 may release vacuum attraction. The polishing pad is formed from, for example, IC1000 manufactured by Rodel Nitta Company, as with the electrolytic polishing apparatus 54.

The CMP apparatus 56 polishes an exposed surface of the barrier film 305 and the copper film 307 (and the seed film 306) remaining on the surface of the substrate, which has been polished by the electrolytic polishing apparatus 54, so as to completely remove unwanted copper film 307 (and the seed film 306), and to remove the barrier film 305. As a result, as shown in FIG. 1C, the interconnect 308 is formed in the insulating film 302.

In this manner, most of the interconnect metal film is removed by the electrolytic polishing process (composite electrolytic polishing process), and subsequently, a remaining interconnect metal film is removed by the conventional CMP process, which can sufficiently eliminate level differences on the surface of the substrate. According to the polishing method of this embodiment, a highly flat surface of the substrate can be obtained. Further, by switching from electrolytic polishing to CMP at a time the barrier film is exposed, the remaining interconnect metal film and the barrier film underneath the interconnect metal film can be sufficiently removed.

After the CMP apparatus 56 finishes polishing, the dresser 39 and the atomizer 45 perform conditioning of the polishing surface of the polishing pad, so that the polishing surface can be ready for subsequent polishing, as with the electrolytic polishing apparatus 54.

According to FIGS. 1A through 1C, the polishing process of the substrate can be divided into several polishing steps: a step of polishing the copper film 307 (Bulk Cu); a step of polishing the copper film 307 and the seed film 306 until the barrier film 305 is exposed (Cu Clear); a step of polishing the barrier film 305 or a hard mask, i.e., a layer formed between the barrier film and the Low-k material (BM/HM Clear); and a step of finish-polishing the insulating film 302, i.e., the Low-k material (Low-k T.U.). Accordingly, several combinations of the polishing processes are available as shown in table below.

TABLE 1

| | 1platen | 2platen(1) | 2platen(2) | 2platen(3) | 3platen(1) | 3platen(2) | 3platen(3) | 4platen(1) | 4platen(2) | 4platen(3) |
|---|---|---|---|---|---|---|---|---|---|---|
| Bulk Cu | ECP-C | ECP-C | ECP-C | ECP-C | ECP-C | ECP-C | ECP-C | ECP-C | ECP-C 1 | ECP-C 1 |
| Cu Clear | | CMP | | | CMP 1 | CMP 1 | | CMP 1 | ECP-C 2 | ECP-C 2 |
| BM/HM Clear | | | CMP | | CMP 2 | | CMP 1 | CMP 2 | CMP 1 | ECP-C 3 |
| Low-k T.U. | | | | CMP | | CMP 2 | CMP 2 | CMP 3 | CMP 2 | CMP |
| | | | | (HM Included) | | | | | | (HM Included) |

In Table 1, “1 platen” means that all steps are performed using one polishing table, and “2 platen”, “3 platen”, and “4 platen” mean that polishing is performed using two, three, and four polishing tables, respectively. ECP-C means an electrolytic polishing process in which the substrate contacts the polishing surface during process. In ECP-C, a liquid such as electrolyte or pure water is supplied, and slurry containing abrasive particles can be used, as needed. Although the polishing process is changed from step to step, only processing conditions may be changed while using the same polishing table.

The substrate, which has been polished by the CMP apparatus 56, is transferred again to the position above the pusher 30′, and is placed onto the pusher 30′. Then, the linear transporter 27B and the lifter 29′ transfer the substrate to the reversing device 28′, where the substrate is reversed. The transfer robot 21 transfers this reversed substrate to the cleaning unit 23. In this cleaning unit 23, as described above, the surface of the substrate is cleaned and rinsed. After cleaning and rinsing, the transfer robot 21 transfers the substrate to the substrate station 50, and places it onto the substrate station 50.

The transfer robot 20 (or 21) removes this cleaned substrate from the substrate station 50, and transfers it to the drying unit 5 (or 6) which may comprise a pen sponge for cleaning the upper surface of the substrate, and may have a spin dry function. The substrate is cleaned and dried by the drying unit 5 (or 6). Then, the transfer robot 4 returns this cleaned and dried substrate to the substrate cassette 1.

Although a semiconductor wafer is used as a substrate to be polished in this embodiment, it should be understood that a substrate to be polished is not limited to a semiconductor wafer. Instead of a polishing cloth, a fixed abrasive pad impregnated with abrasive particles or a polishing pad containing no abrasive particles may be used as the polishing pad 66 of the electrolytic polishing apparatus 54 and/or the polishing pad of the CMP apparatus 56. The fixed abrasive pad has a relatively hard polishing surface which can be self-regenerated after the polishing surface is destroyed.

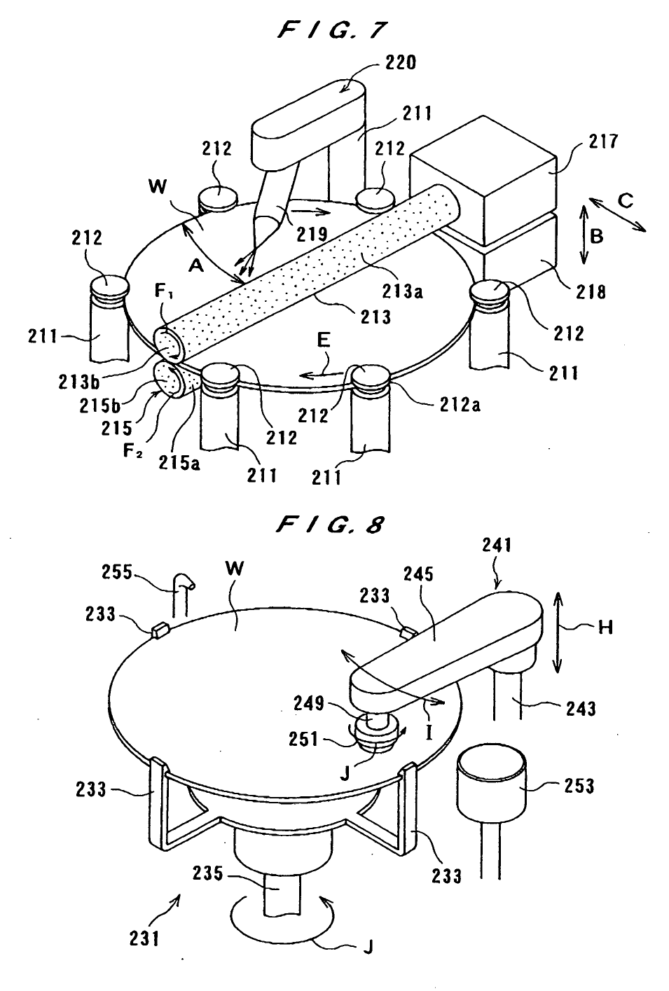

As shown in FIG. 7, each of the cleaning units 22 and 23 may comprise a plurality of (six in FIG. 7) spindles 211 for holding a peripheral portion of the substrate W, two roll-type cleaning members 213 and 215 disposed above and below the substrate W, respectively, drive mechanisms 217 and 218 for moving rotation shafts 213b and 215b, which are disposed in parallel with the surface of the substrate W, toward and away from the substrate W and for rotating the rotation shafts 213b and 215b in directions indicated by arrows F₁ and F₂, respectively, and a rinsing liquid supply nozzle 219 for supplying a rinsing liquid such as pure water onto a surface of the substrate W.

The rinsing liquid supply nozzle 219 may comprise an ultrasonic nozzle which applies an ultrasonic energy to a rinsing liquid to be ejected, a cavitation nozzle which generates cavitations in a rinsing liquid to be ejected, or an ultrasonic cavitation nozzle which applies an ultrasonic energy to and generates cavitations in a rinsing liquid to be ejected. The rinsing liquid supply nozzle 219 is provided on a swing arm 220, and is swung by a swing shaft 221 in a direction indicated by arrow A while supplying the rinsing liquid onto the surface of the substrate W. The rinsing liquid supply nozzle 219 is operable to stop its movement at a desired position above the substrate W and at a given waiting position. Although not shown in the drawings, a nozzle for supplying a rinsing liquid onto a lower surface (a rear surface) of the substrate W is also provided.

The roll-type cleaning members 213 and 215 comprise cylindrical members 213a and 215a formed from a porous PVF sponge, and the rotation shafts 213b and 215b extending through the cylindrical members 213a and 215a, respectively. Test results show that a smaller average diameter of holes of a sponge forming the cylindrical members 213a and 215a results in a better capability of removing dusts (particles). A preferable average diameter of the holes of the sponge is not more than 110 μm. The cylindrical members 213a and 215a may be made of urethane foam. The drive mechanisms 217 and 218 are moved respectively by non-illustrated moving mechanisms so as to vertically move away from the substrate W as indicated by arrow B, and to move to waiting positions as indicated by arrow C.

Cleaning and rinsing of the substrate W are performed as follows. With the surface, to be cleaned, facing upwardly, a peripheral portion of the substrate W is held and pressed by circumferential grooves formed on tops 212 on upper portions of the spindles 211. The tops 212 are rotated at an equal high speed to thereby rotate the substrate W at a substantially constant speed in a direction indicated by arrow E. Subsequently, the roll-type cleaning members 213 and 215 are brought into contact with the upper and lower surfaces of the substrate W. respectively, and at the same time, a rinsing liquid with an ultrasonic energy applied thereto is ejected, or a rinsing liquid with cavitations generated therein is ejected, or a rinsing liquid with an ultrasonic energy and cavitations is ejected through the rinsing liquid supply nozzle 219. At this time, a rinsing liquid is supplied onto the lower surface of the substrate W through the non-illustrated rinsing liquid supply nozzle. In this manner, particles adhering to the upper and lower surfaces of the substrate W are removed and washed away by the rinsing liquid.

As shown in FIG. 8, each of the cleaning units 22 and 23 may be a pencil-type cleaning unit comprising a rotating chuck mechanism 231 and a pencil-type brush cleaning mechanism 241. The rotating chuck mechanism 231 has chuck claws 233 at an upper portion thereof for holding a peripheral portion of the disk-shaped substrate W, and is rotated by a rotating drive shaft 235 in a direction indicated by arrow G. The chuck claws 233 of the rotating chuck mechanism 231 have a non-illustrated opening mechanism for allowing the substrate W to be transferred to and removed from the rotating chuck mechanism 231 by a hand of a transfer robot.

Each of the cleaning units 22 and 23 has a swing arm 245 having one end fixed to a shaft 243. A rotating drive shaft 249 extends downwardly from another end of the swing arm 245 toward the surface (to be cleaned) of the substrate W. A pencil-type cleaning member 251 formed from a porous PVF sponge is attached to a lower end of the rotating drive shaft 249. The pencil-type cleaning member 251 may be made of foamed polyethylene. The pencil-type cleaning member 251 has a substantially column shape having a horizontal bottom surface to be brought into contact with the substrate W. The pencil-type cleaning member 251 has a height of about 5 mm, and a diameter of about 20 mm. An average diameter of fine holes formed in the sponge is about 110 μm. Generally, the smaller the average diameter of the fine holes, the greater cleaning effect of the sponge. Therefore, a preferable diameter of the fine holes is less than 80 μm.

The shaft 243 is vertically movable as indicated by arrow H, and the swing arm 245 is swung by the shaft 243 in a direction indicated by arrow I. The pencil-type cleaning member 251 is rotated by the rotating drive shaft 249 in a direction indicated by arrow J. Each of the cleaning units 22 and 23 comprises a rinsing liquid supply nozzle 255 for supplying a rinsing liquid to the substrate W, and a cup-shaped brush storage 253 for storing and cleaning the pencil-type cleaning member 251 while the pencil-type brush cleaning mechanism 241 is not in operation.

The cleaning units 22 and 23 operate as follows. The chuck claws 233 hold a peripheral portion of the substrate W, and in this state, the rotating chuck mechanism 231 in its entirety is rotated by the rotating drive shaft 235 at a high speed to thereby rotate the substrate W at a predetermined speed in the range of 500 to 1500 min⁻¹. A rotational speed of the substrate W rotated by the rotating chuck mechanism 231 during cleaning is controlled by a non-illustrated rotation control unit coupled to the rotating drive shaft 235, and can be selected within a range of permissible rotational speed, e.g., several thousands min⁻¹. The bottom surface of the rotating pencil-type cleaning member 251 is brought into contact with the surface (upper surface) of the substrate W. In this state, the rinsing liquid is supplied onto the upper surface of the substrate W through the rinsing liquid supply nozzle 255, and simultaneously the swing arm 245 is swung to thereby clean and rinse the substrate W.

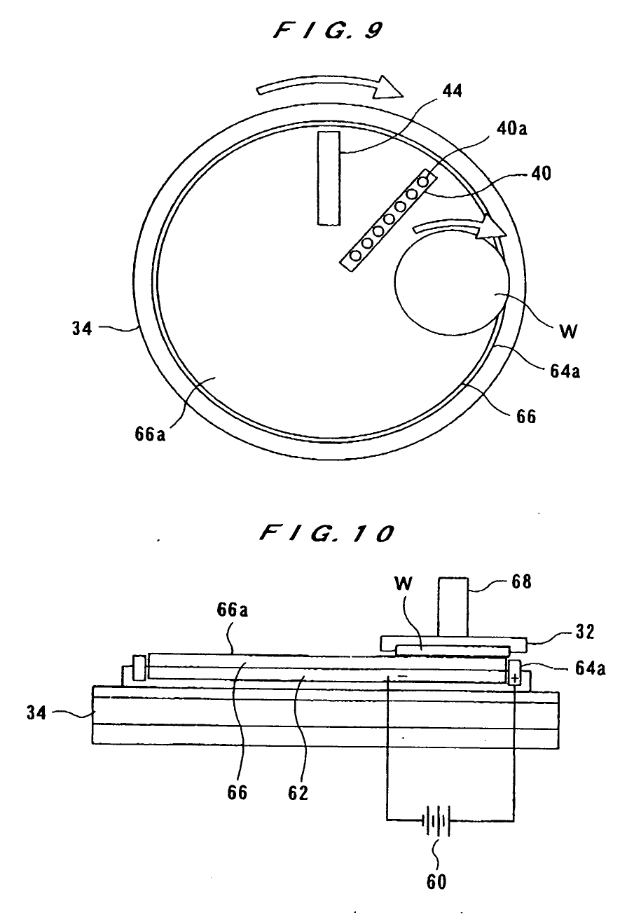

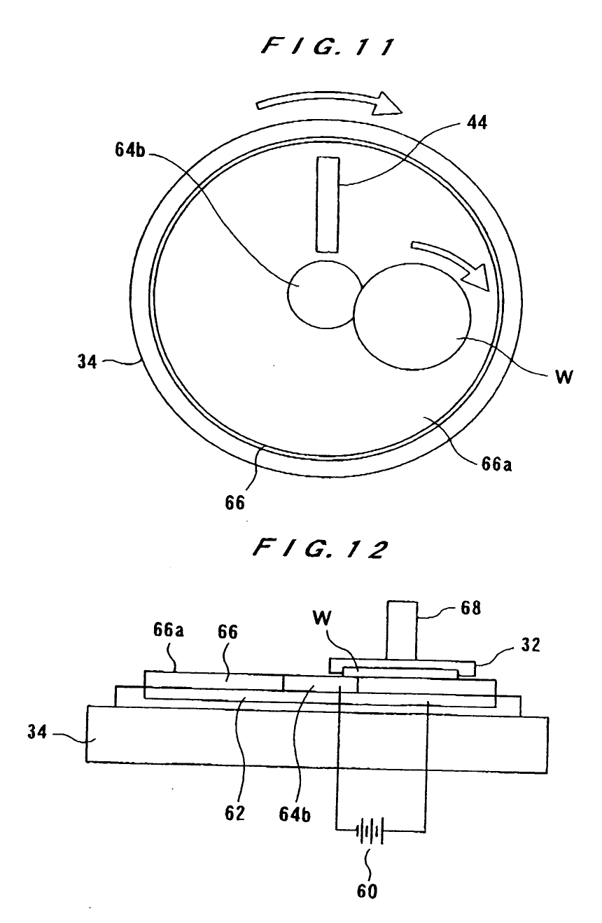

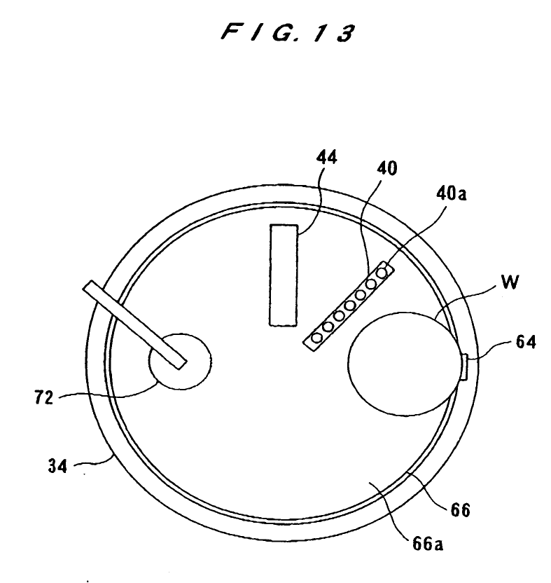

FIGS. 9 and 10 show an essential part of an electrolytic polishing apparatus according to another embodiment of the present invention. The embodiment shown in FIGS. 9 and 10 is different from the embodiment shown in FIGS. 3 and 4 in that, instead of the rod-like second electrode (anode) 64, a ring-shaped second electrode 64a is provide around first electrode 62 such that these electrodes 62 and 64a are electrically insulated from each other. According to this embodiment, while top ring 32 and polishing table 34 are rotated to polish a substrate held by the top ring 32, the second electrode 64a and a conductive film such as a copper film 307 (see FIG. 1B) can be held in contact with each other at all times.

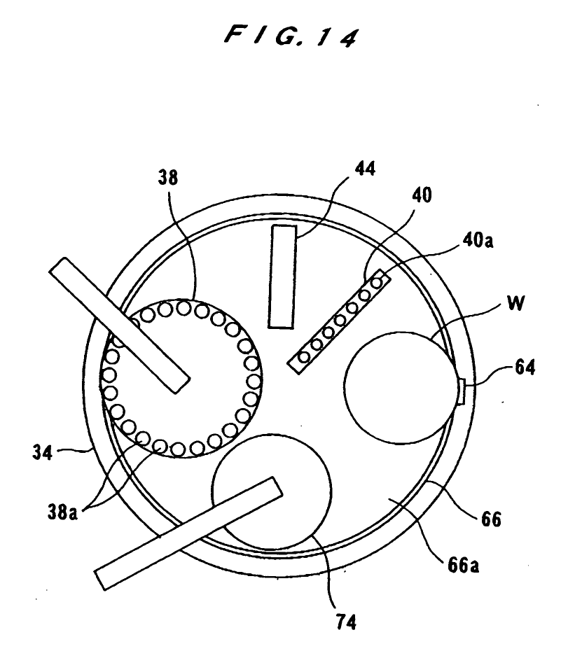

FIGS. 11 and 12 show an essential part of an electrolytic polishing apparatus according to another embodiment of the present invention. The embodiment shown in FIGS. 11 and 12 is different from the embodiment shown in FIGS. 3 and 4 in that, instead of the rod-like second electrode (anode) 64, a small disk-shaped second electrode 64b is provide at a central portion of first electrode 62 such that these electrodes 62 and 64b are electrically insulated from each other. In addition, a central hole is formed in polishing pad 66 at a position corresponding to the second electrode 64a so that a surface of the second electrode 64b is exposed. In this embodiment also, while top ring 32 and polishing table 34 are rotated to polish a substrate held by the top ring 32, the second electrode 64b and a conductive film such as a copper film 307 (see FIG. 1B) can be held in contact with each other at all times.

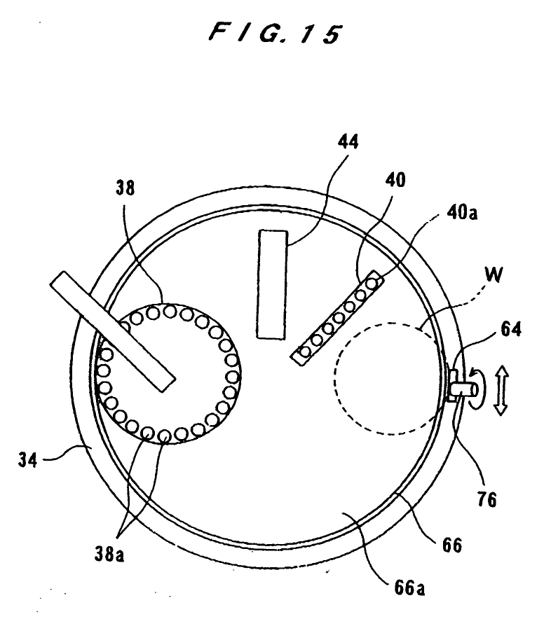

FIG. 13 shows an essential part of an electrolytic polishing apparatus according to another embodiment of the present invention. The embodiment shown in FIG. 13 is different from the embodiment shown in FIGS. 3 and 4 in that, instead of the dresser 38, a small-diameter scan dresser 72 having diamond particles electrodeposited on an entire small-circular lower surface thereof is used as a conditioning member. This small-diameter scan dresser 72 is operable to dress (condition) polishing surface 66a of polishing pad 66 in its original place, i.e., in a so-called in-situ manner.

FIG. 14 shows an essential part of an electrolytic polishing apparatus according to another embodiment of the present invention. The electrolytic polishing apparatus of this embodiment comprises, in addition to the embodiment shown in FIGS. 3 and 4, a counter electrode 74 vertically movable between a predetermined position above polishing pad 66 and a waiting position. The counter electrode 74 is made of, for example, bulk Pt.

During electrolytic polishing, polishing by-products may be deposited on a surface of first electrode (cathode) 62 (see FIG. 4). If such polishing by-products remain as they are, electrode potential and electrode resistance would be changed, and a polishing property would be adversely affected. According to this embodiment, at a time of interval, e.g., a time of replacement of a substrate, the counter electrode 74 is periodically brought into contact with the polishing surface 66a of the polishing table 66 while the counter electrode 74 and the polishing surface 66a are moved relative to each other. In this state, an electrolytic solution is supplied onto the polishing surface 66a, and simultaneously a voltage is applied between the first electrode 62 and the counter electrode 74 such that the first electrode 62 has polarity reversed from when electrolytic polishing is performed, thereby conditioning the first electrode 62.

In this manner, the polishing by-products deposited on the first electrode 62 due to electrolytic polishing are transferred to the counter electrode 74 and removed from the first electrode 62. Therefore, electrode potential and electrode resistance, which affect a polishing property, can be prevented from changing.

Dresser 38 may be made of material having good conductivity so that the dresser 38 can serve as the counter electrode.

FIG. 15 shows an electrolytic polishing apparatus according to another embodiment of the present invention. The electrolytic polishing apparatus of this embodiment comprises, in addition to the embodiment shown in FIGS. 3 and 4, an electrode conditioner 76 which is vertically movable and rotatable. The electrode conditioner 76 is movable between a predetermined position above second electrode 64 and a waiting position, and is reciprocated in a horizontal direction. The electrode conditioner 76 is made of PVA sponge, polyester nonwoven fabric, or the like. The electrode conditioner 76 is operable to scrub and clean a surface (upper surface) of the second electrode 64 while a cleaning liquid, water, or dilute acid (e.g, at most 1 wt % of sulfuric acid, hydrochloric acid, nitric acid, or citric acid) is supplied onto the surface of the second electrode 64. For example, the electrode conditioner 76 is rotated and reciprocated while pressing the surface (upper surface) of the second electrode 64, and simultaneously water is supplied onto the surface of the second electrode 64, whereby substances adhering to the second electrode 64 are removed. When an oxide adheres to the second electrode 64, the dilute acid is supplied instead of water so as to remove the oxide.

The second electrode 64 has an exposed surface, and hence, during electrolytic polishing, polishing by-products, the oxide, and the like adhere to the exposed surface. According to this embodiment, at a time of interval, e.g., a time of replacement of a substrate, the electrode conditioner 76 can periodically condition the second electrode 64 to remove such polishing by-products, the oxide, and the like deposited on the surface of the second electrode 64 during polishing.

Although not shown in the drawings, it is preferable that the electrolytic polishing apparatus comprises an electrode conditioner cleaning unit for cleaning the electrode conditioner 76 so that the electrode conditioner cleaning unit periodically cleans the electrode conditioner 76.

In the above-mentioned embodiments, electrolytic polishing and CMP are independently performed by the electrolytic polishing apparatus 54 and the CMP apparatus 56, respectively. However, the electrolytic polishing apparatus 54 shown in FIGS. 3 and 4 may be designed such that the electrolytic solution supply nozzle 40 as a liquid supply unit can selectively supply an electrolytic solution or a polishing liquid onto the polishing pad 66, so that the electrolytic polishing apparatus 54 can perform both electrolytic polishing and CMP.

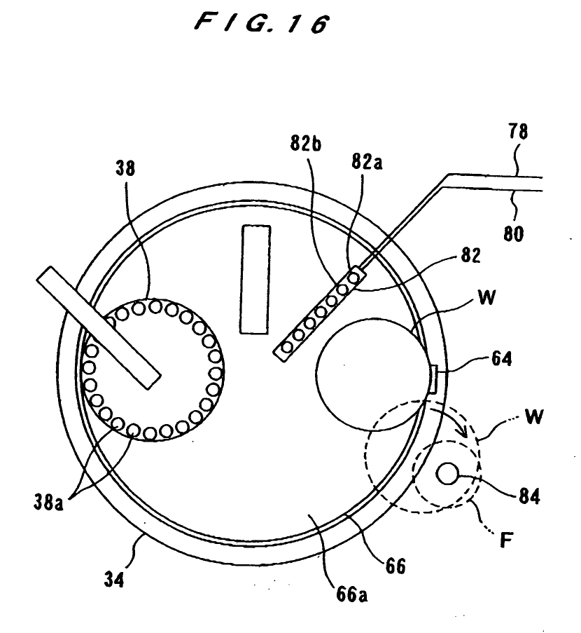

FIG. 16 shows an essential part of an electrolytic polishing apparatus according to another embodiment of the present invention, This electrolytic polishing apparatus is operable to perform both electrolytic polishing and CMP, and is different from that shown in FIGS. 3 and 4 in that, instead of the electrolytic solution supply nozzle 40, a liquid supply nozzle 82 connected to an electrolytic solution supply line 78 and a polishing liquid supply line 80 is used as a liquid supply unit. With this structure, the liquid supply nozzle 82 can selectively supply an electrolytic solution or a polishing liquid without mixing them with each other. The liquid supply nozzle 82 has electrolytic solution supply mouths 82a through which the electrolytic solution is supplied, and polishing liquid supply mouths 82b through which the polishing liquid is supplied. The electrolytic solution supply mouths 82a and the polishing liquid supply mouths 82b are alternately arranged.

In this embodiment, a substrate is held by top ring 32 and pressed against polishing surface 66a of polishing pad 66 at predetermined pressure, and the top ring 32 and polishing table 34 are rotated together with each other, At the same time, the electrolytic solution is supplied onto the polishing surface 66a through the electrolytic solution supply mouths 82a of the liquid supply nozzle 82, and a predetermined voltage is applied between first electrode 62 and second electrode 64 to thereby perform electrolytic polishing.

CMP is performed as follows. A substrate is held by the top ring 32 and pressed against the polishing surface 66a of the polishing pad 66 at predetermined pressure, and the top ring 32 and the polishing table 34 are rotated together with each other. At the same time, the polishing liquid is supplied onto the polishing surface 66a through the polishing liquid supply mouths 82b of the liquid supply nozzle 82 without applying a voltage between the first electrode 62 and the second electrode 64 to thereby perform CMP.

After performing electrolytic polishing in this electrolytic polishing apparatus, the substrate is transferred to the cleaning unit 22, where the substrate is cleaned and rinsed, as previously described. After cleaning and rinsing, the top ring 32 of the electrolytic polishing apparatus holds the substrate again to perform CMP.

Cleaning and rinsing of the substrate to which the electrolytic solution is attached is preferably performed until electrical conductivity of a waste rinsing liquid discharged from this cleaning and rinsing process is reduced to at most one-tenth of electrical conductivity of the polishing liquid used in the CMP process, as with the above mentioned embodiments. The electrical conductivity of the waste rinsing liquid discharged through discharge passage 122 is monitored by electrical conductivity meter 124 (see FIG. 5) so that an effect of cleaning and rinsing can be confirmed and polishing can be sufficiently performed.

Conditioning of the polishing surface 66a by dresser 38 and atomizer 44 is performed between electrolytic polishing and CMP. After conditioning, it is preferable that the polishing table 34 is rotated at a speed in the range of 50 to 100 min⁻¹ for several seconds so as to drain the polishing pad 66.

Depending on types of electrolytic solution (polishing liquid), a slight change in concentration (particularly due to mixing of water) may cause a change in physical properties of the solution, i.e., a change in a polishing property. Generally, conditioning such as dressing and atomizing uses water, and such water remaining after conditioning may cause a change in concentration. Therefore, removal of water (i.e., draining) is required. Thus, after conditioning, the polishing table 34 with the polishing pad 66 is rotated at a speed in the range of 50 to 100 min⁻¹ for several seconds so as to drain the polishing pad 66, whereby a concentration of the electrolytic solution (polishing liquid) can be prevented from changing.

In the embodiment shown in FIG. 16, a rinsing liquid supply nozzle 84 for upwardly ejecting a rinsing liquid such as pure water is disposed laterally of the polishing table 34. With this arrangement, the top ring 32 holds and elevates the substrate W after electrolytic polishing, and then moves the substrate W to an overhanging position where part of the substrate W projects from an edge of the polishing table 34 so that the substrate W is positioned above the rinsing liquid supply nozzle 84. Thereafter, the substrate W is rotated, and a rinsing liquid is supplied toward a surface (lower surface) of the substrate W over an area F through the rinsing liquid supply nozzle 84 to thereby rinse the lower surface of the substrate W.

According to this embodiment, electrolytic polishing, cleaning and rinsing, and CMP can be successively performed on the substrate W while the top ring 32 holds the substrate W.

In a case of polishing copper by electrolytic polishing and then performing CMP to completely remove copper remaining on a surface of a barrier film, an electrolytic solution for use in electrolytic polishing may comprise a supporting electrolyte and a polishing liquid to be used in CMP . FIG. 17 shows another embodiment of an essential part of an electrolytic polishing apparatus designed to use such an electrolytic solution comprising a supporting electrolyte and a polishing liquid to be used in CMP so as to perform both electrolytic polishing and CMP.

The electrolytic polishing apparatus of this embodiment comprises a liquid supply nozzle 86 as a liquid supply unit located above polishing pad 66. The liquid supply nozzle 86 is connected to a pure water supply line 88 through which only pure water is delivered, a supporting electrolyte supply line 90 through which a liquid containing only a supporting electrolyte is delivered, a polishing liquid supply line 92 through which only a polishing liquid (complexing agent, anticorrosive, abrasive particles) is delivered, and an additive supply line 94 through which a liquid containing only an additive (oxidizing agent) is delivered. Theses supply lines 88, 90, 92 and 94 are capable of adjusting supply flow rate within the range of for example, 0.01 to 0.5 L/min.

Additionally, the liquid supply nozzle 86 has a pure water supply mouth 96a, a supporting electrolyte supply mouth 96b, a polishing liquid supply mouth 96c, and an additive supply mouth 96d. Pure water, which is delivered through the pure water supply line 88, is supplied onto the polishing pad 66 through the pure water supply mouth 96a. The liquid containing only the supporting electrolyte, which is delivered through the supporting electrolyte supply line 90, is supplied onto the polishing pad 66 through the supporting electrolyte supply mouth 96b. The polishing liquid, which is delivered through the polishing liquid supply line 92, is supplied onto the polishing pad 66 through the polishing liquid supply mouth 96c. The liquid containing only the additive, which is delivered through the additive supply line 94, is supplied onto the polishing pad 66 through the additive supply mouth 96d. The supply mouths 96a, 96b, 96c and 96d may comprise plural supply mouths, respectively.

According to this embodiment, electrolytic polishing can be performed while the liquid containing only the supporting electrolyte and the polishing liquid are supplied onto the polishing pad 66 through the supporting electrolyte supply mouth 96b and the polishing liquid supply mouth 96c, respectively. Thereafter, CMP can be performed while the polishing liquid and the liquid containing only the additive are supplied onto the polishing pad 66 through the polishing liquid supply mouth 96c and the additive supply mouth 96d, respectively. Further, after polishing (electrolytic polishing and CMP), water polishing can be performed while pure water is supplied onto the polishing pad 66 through the pure water supply mouth 96a, thus cleaning the substrate that has been polished.

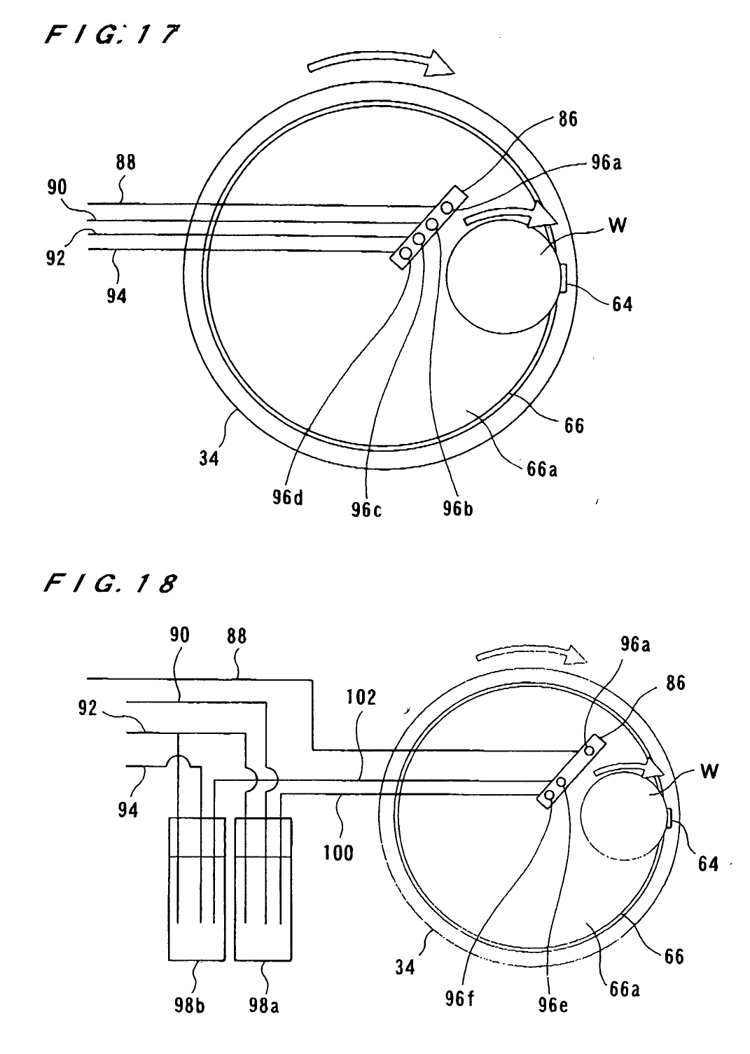

FIG. 18 shows an essential part of an electrolytic polishing apparatus according to another embodiment of the present invention- The embodiment shown in FIG. 18 is different from the embodiment shown in FIG. 17 in the following points. Supporting electrolyte supply line 90 and polishing liquid supply line 92 are connected to a first buffer 98a, and the polishing liquid supply line 92 and additive supply line 94 are connected to a second buffer 98b. The first buffer 98a and liquid supply nozzle 86 are connected through an electrolytic solution supply line 100. The second buffer 98b and the liquid supply nozzle 86 are connected through an additive-containing polishing liquid supply line 102. The liquid supply nozzle 86 has an electrolytic solution supply mouth 96e through which an electrolytic solution, which is supplied through the electrolytic solution supply line 100, is supplied onto the polishing pad 66. The liquid supply nozzle 86 also has an additive-containing polishing liquid supply mouth 96f through which an additive-containing polishing liquid, which is supplied through the additive-containing polishing liquid supply line 102, is supplied onto the polishing pad 66.

The electrolytic solution supply line 100 and the additive-containing polishing liquid supply line 102 are capable of adjusting supply flow rate within the range of, for example, 0.1 to 1.0 L/min. The electrolytic solution supply mouth 96e and the additive-containing polishing liquid supply mouth 96f may comprise plural mouths, respectively.

According to this embodiment, the liquid, which contains only the supporting electrolyte, and the polishing liquid are supplied to the first buffer 98a, where these liquids are mixed with each other to produce in advance an electrolytic solution stored in the first buffer 98a. Then, electrolytic polishing is performed while supplying the electrolytic solution from the first buffer 98a onto the polishing pad 66. Further, the polishing liquid and the additive are supplied to the second buffer 98b, where the polishing liquid and the additive are mixed with each other to produce in advance an additive-containing polishing liquid stored in the second buffer 98b. Then, CMP is performed while supplying the additive-containing polishing liquid from the second buffer 98b onto the polishing pad 66. In this case, the additive is supplied to the second buffer 98b according to need.

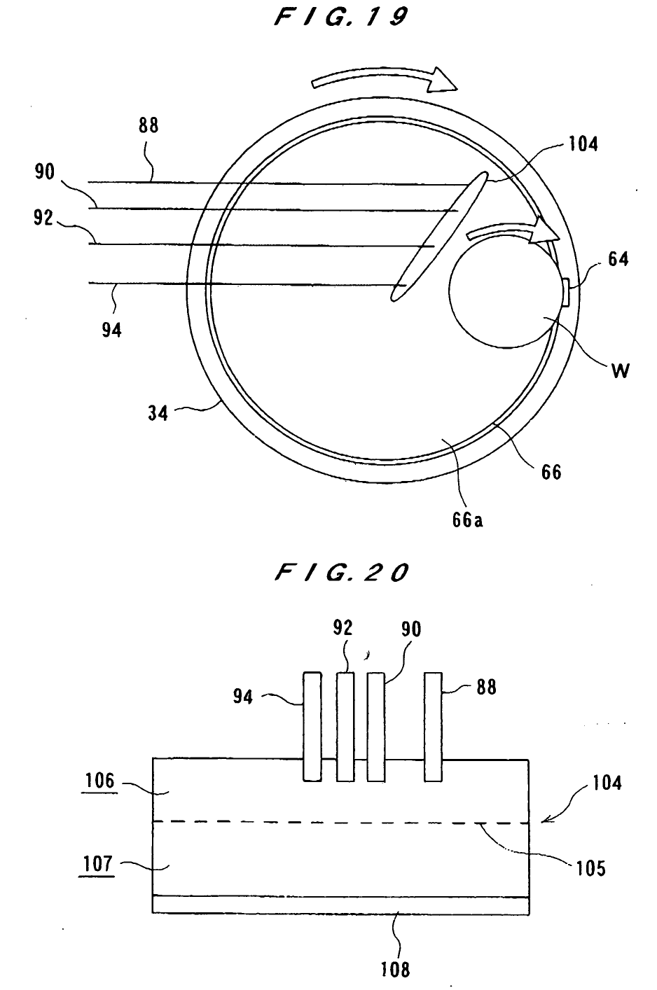

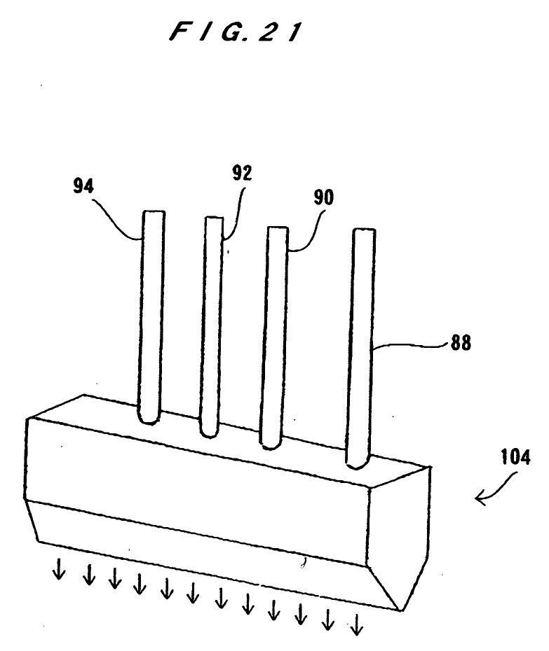

FIGS. 19 through 21 show an essential part of an electrolytic polishing apparatus according to another embodiment of the present invention. This embodiment is different from the embodiment shown in FIG. 17 in that, instead of the liquid supply nozzle 86 having the plural supply mouths, a slit nozzle 104 is used as a liquid supply unit. This slit nozzle 104 has a slit mouth extending in a longitudinal direction thereof and disposed at a lower end thereof. As shown in FIG. 20, a baffle 105 for mixing liquids is disposed in the slit nozzle 104, and an inside space of the slit nozzle 104 is divided by the baffle 105 into a mixing bath 106 and a buffer bath 107. A dispersing layer 108, which is formed from a mesh or a porous material, is attached to the slit mouth. The dispersing layer 108 may be held in contact or non-contact with polishing surface 66a of polishing pad 66 during polishing.

According to this embodiment, a liquid containing only a supporting electrolyte is supplied through supporting electrolyte supply line 90 to the slit nozzle 104, and a polishing liquid is supplied through polishing liquid supply line 92 to the slit nozzle 104. In the slit nozzle 104, the liquid containing only the supporting electrolyte and the polishing liquid are mixed with each other to produce an electrolytic solution right before polishing. This electrolytic solution is supplied onto the polishing pad 66, and electrolytic polishing is thus performed. Further, a polishing liquid is supplied through the polishing liquid supply line 92 to the slit nozzle 104, and an additive, if necessary, is also supplied through the additive supply line 94 to the slit nozzle 104, where the polishing liquid and the additive are mixed with each other to produce an additive-containing polishing liquid right before polishing. This additive-containing polishing liquid is supplied onto the polishing pad 66, and CMP is thus performed. According to this embodiment, the electrolytic solution and the additive-containing polishing liquid can be uniformly supplied onto the polishing pad 66 through a lower end of the slit nozzle 104.

Although two-step polishing is performed to remove the barrier film and the copper film (and the seed film) on the substrate W in the above-mentioned embodiments, the present invention is not limited to this manner. For example, the copper film (and the seed film) may be polished by two-step polishing comprising electrolytic polishing and CMP, and then remaining copper film (and the seed film) and the barrier film may be removed respectively by different steps of CMP. In this manner, more than two-step polishing can be performed to polish the surface of the substrate.

What is claimed is:

1. A polishing method of polishing a substrate so as to remove an interconnect metal film and a barrier film formed on portions other than interconnect recesses, said method comprising:
performing a first polishing process of polishing a surface of the substrate;
after performing said first polishing process, cleaning the surface of the substrate; and then
performing a second polishing process of further polishing the surface of the substrate,
wherein at least one of performing said first polishing process and performing said second polishing process comprises performing electrolytic polishing.

2. The polishing method according to claim 1, wherein said electrolytic polishing is performed using an electrolytic solution having an electrical conductivity of not less than 50 mS/cm.

3. The polishing method according to claim 1, wherein at least one of performing said first polishing process and performing said second polishing process comprises performing CMP.

4. The polishing method according to claim 1, wherein cleaning the surface of the substrate comprises cleaning and rinsing the surface of the substrate using a cleaning unit.

5. The polishing method according to claim 1, wherein cleaning the surface of the substrate comprises performing a water polishing process of polishing the substrate on a polishing table while supplying water to the substrate.

6. The polishing method according to claim 1, wherein cleaning the surface of the substrate comprises rinsing the surface of the substrate at a position laterally of a polishing table.

7. The polishing method according to claim 1, wherein cleaning the surface of the substrate comprises cleaning the surface of the substrate until an electrical conductivity of a waste cleaning liquid discharged during cleaning the surface of the substrate is reduced to at most one-third of an electrical conductivity of a polishing liquid used in said second polishing process.

8. The polishing method according to claim 1, further comprising monitoring an electrical conductivity of a waste cleaning liquid discharged during cleaning the surface of the substrate using an electrical conductivity meter.

9. The polishing method according to claim 1, further comprising conditioning a polishing surface before or after performing said electrolytic polishing.

10. A polishing apparatus, comprising:
a first polishing unit including an electrolytic polishing apparatus for polishing a substrate;
at least one cleaning unit for cleaning and rinsing the substrate;
a second polishing unit for further polishing the substrate after processed by said electrolytic polishing apparatus and said at least one cleaning unit; and
at least one drying unit for drying the substrate.

11. The polishing apparatus according to claim 10, wherein said second polishing unit includes a CMP apparatus.

12. The polishing apparatus according to claim 11, wherein said electrolytic polishing apparatus comprises a conditioning member for conditioning a polishing surface, and also serves as said CMP apparatus.

13. The polishing apparatus according to claim 10, further comprising an electrical conductivity meter provided in a drain passage of said cleaning unit for measuring electrical conductivity of a waste rinsing liquid flowing through said drain passage.

14. An electrolytic polishing apparatus, comprising:
a first electrode connected to one of poles of a power source;
a polishing table electrically connected to said first electrode;
a polishing pad provided on an upper surface of said polishing table and having a polishing surface;
a top ring operable to hold a substrate and press the substrate against said polishing surface at a pressure of not more than 7 kPa;
a second electrode connected to another of the poles of the power source for supplying electricity to the substrate;
a liquid supply unit for supplying a liquid onto said polishing surface;
a conditioning member for conditioning said polishing surface; and
a relative movement mechanism for providing relative movement between the substrate held by said top ring and said polishing pad.

15. The electrolytic polishing apparatus according to claim 14, wherein said conditioning member comprises one of a dresser having diamond particles electrodeposited thereon and a brush.

16. The electrolytic polishing apparatus according to claim 14, further comprising a counter electrode disposed so as to face said first electrode for conditioning said first electrode by applying a voltage such that said first electrode has polarity reversed from when electrolytic polishing is performed.

17. The electrolytic polishing apparatus according to claim 14, further comprising an atomizer for supplying pure water or a chemical liquid onto said polishing surface.

18. The electrolytic polishing apparatus according to claim 14, wherein said polishing pad comprises one of a polishing pad having through-holes extending therethrough in a direction perpendicular to said polishing surface, and a polishing pad made of material having liquid permeability.

19. The electrolytic polishing apparatus according to claim 14, further comprising an electrode conditioner for conditioning said second electrode.

20. The electrolytic polishing apparatus according to claim 19, further comprising an electrode conditioner cleaning unit for cleaning said electrode conditioner.

21. The electrolytic polishing apparatus according to claim 16, further comprising a counter electrode conditioner for conditioning said counter electrode.

22. An electrolytic polishing apparatus, comprising:
a first electrode connected to one of poles of a power source;
a polishing table electrically connected to said first electrode;
a polishing pad provided on an upper surface of said polishing table and having a polishing surface;
a top ring operable to hold a substrate and press the substrate against said polishing surface;
a second electrode connected to another of the poles of the power source for supplying electricity to the substrate;
a liquid supply unit for supplying a liquid onto said polishing surface;
a conditioning member for conditioning said polishing surface; and
a relative movement mechanism for providing relative movement between the substrate held by said top ring and said polishing pad,
wherein said liquid supply unit is connected to a polishing liquid supply line and an electrolytic solution supply line.

23. The electrolytic polishing apparatus according to claim 22, wherein said liquid supply unit is further connected to a pure water supply line.

24. An electrolytic polishing apparatus, comprising:
a first electrode connected to one of poles of a power source;
a polishing table electrically connected to said first electrode;
a polishing pad provided on an upper surface of said polishing table and having a polishing surface;
a top ring operable to hold a substrate and press the substrate against said polishing surface;
a second electrode connected to another of the poles of the power source for supplying electricity to the substrate;
a liquid supply unit for supplying a liquid onto said polishing surface;
a conditioning member for conditioning said polishing surface; and
a relative movement mechanism for providing relative movement between the substrate held by said top ring and said polishing pad,
wherein said liquid supply unit is connected to a polishing liquid supply line and a supporting electrolyte supply line.

25. The electrolytic polishing apparatus according to claim 24, wherein said liquid supply unit is further connected to an additive supply line.

26. The electrolytic polishing apparatus according to claim 24, wherein the polishing liquid supply line and the supporting electrolyte supply line are connected to said liquid supply unit via a buffer for mixing liquids.

27. The electrolytic polishing apparatus according to claim 24, wherein said liquid supply unit is further connected to a pure water supply line.
